(19) United States
(12) Patent Application Publication
(10) Pub. No.: US 2018/0173264 A1
(43) Pub. Date: Jun. 21, 2018

(54) NGPR-1 Nano Grid Power Router

(71) Applicant: Jon Sprinkle, Lufkin, TX (US)

(72) Inventor: Jon Sprinkle, Lufkin, TX (US)

(21) Appl. No.: 15/379,763

(22) Filed: Dec. 15, 2016

(51) Int. Cl. G05F 1/66; G01R 21/133; G05B 15/02

(52) U.S. Cl. CPC G05F 1/66; Y10S 977/948; G05B 15/02; G01R 21/133

(57) ABSTRACT

The UNIVERSAL NANOGRID OPERATOR can be installed in any nanogrid system, partial or complete, and will control all relevant aspects of nanogrid operations using no collaboration with existing proprietary control systems within the nanogrid.

THE UNIVERSAL NANOGRID OPERATOR uses a generic set of sensor kits to directly monitor nanogrid power nodes in real time and references this data to preselected activity paths. Generic transducer kits installed throughout the nanogrid are then engaged as needed to position the nanogrid equipment electrically and operationally within the nanogrid. This positioning establishes power routes which enable predictable existing equipment operational protocols which accomplish planned nanogrid functions in real time.

Using the UNIVERSAL NANOGRID OPERATOR enables the nanogrid designer to use any brand of equipment and/or to change design in midstream without costly control engineering.

### (MARK 1)

With the advance of various brandings and proprietary control protocols in the renewable energy field, someone who is a first adopter or who invests in a partial micro/nanogrid with a view towards expansion will likely find it necessary to navigate a virtual mine field in control applications as devices are added to existing investments in on-site energy generation and storage.

Looking ahead five years or so it is also likely that the choices will be fewer as large corporations try to take their market share by brute force of investment and locked-in proprietary programming of all devices associated with behind the meter storage, generation, PV smoothing, demand profiles, quick response and other aggregated assets and arbitrage opportunities.

There are not many high quality products available now which allow complete micro/nanogrid construction and operation at a price reachable by the average individual or small business. Thus far, an investor has to stay “in the fold” of a chosen brand to make use of existing control protocols as the micro/nanogrid is brought into the utility grid storage and ancillary services market via aggregation groupings and for energy arbitrage opportunity. Or the person must invest in barely ready digital control oversight programs which will have to be constantly updated, tweaked, and protected from cyber-attacks.

The small micro/nanogrid owner needs a control system which is universally applicable to the various equipment brands on display for integration into their equipment groupings and which is not vulnerable to off-site cyber-attacks. The ability to protect against EMP events on the grid is also on the list of desirable traits for a micro/nanogrid and control system. This Universal Nanogrid Operator (Mark 1) provides just that, with its “novelty” based on its being both deliberately “brand agnostic” and on its position in the system being as an “operator” rather than just as a controller answering to a “higher” power. The Mark 1 system provides an impenetrable buffer against hostile cyber takeover efforts. It is also impervious to utility grid EMP events when the micro/nanogrid is in the “Fortress” mode which “islands” it from all utility feeds.

When the Mark 1 is implemented as the operator of a micro/nanogrid, all sensor and control nodes are accessible to the main Operator unit just as would be if the micro/nanogrid was being operated by humans who watch dials, gauges, indicator lights, monitor screens, etc. to decide which switches and routines to engage or disengage throughout their work shifts. Rather than get the operator data from the equipment on the micro/nanogrid, the Mark 1 gets the necessary data directly from the sensor nodes which are spread strategically throughout the micro/nanogrid without consulting the branded and proprietary equipment groupings which may be deployed.

Operating the micro/nanogrid in this fashion allows changing of devices, equipment, brands, and protocols with little or no effect on the micro/nanogrid operating system and allows for a small number of prepackaged micro/nanogrid control “kits” to match a great variety of micro/nanogrid equipment groupings. New equipment may be installed almost as if a human operator would be monitoring and directing equipment operations, thus leaving the control interface simple and pre-translated from digital protocols to high level operating decisions implemented mostly by simple switch on/off decisions.

The Mark 1 system can be a single circuit board unit or a combination of units either in one location or spread throughout the nanogrid.

A natural benefit which is appealing from a prepper viewpoint is the autonomous energy backup system provided by the Mark 1 operated micro/nanogrid if the utility grid fails or if the micro/nanogrid is intentionally placed in a standalone or “island” mode. Even when there is no dispatch engine to direct aggregated ancillary services for the utility grid, these universally operated micro/nanogrids will stand alone and provide backup power for the local residence or small business location. The Mark 1 will seamlessly make the transitions from on-grid to off-grid and continue operating the now islanded micro/nanogrid for the benefit of those who were connected behind the meter without communication logjams which are more likely to occur during emergency situations affecting the utility grid. As an additional benefit, if the off-grid PV generating source is AC coupled the Mark 1 can accomplish universal “smart charging” of different battery storage chemistries and types , thus prolonging the usable life of the storage battery. This is accomplished with any brand of micro-inverter or AC coupled inverter/charger by controlling the number of panels actually involved in generation along with optional diversion loads to allow the right amount of charge capability for a given situation of insolation, load, and battery condition.

The Universal Nanogrid Operator (Mark 1) is a product which takes the place of a human operator to inexpensively monitor, analyze, decide, and control all relevant aspects of a micro/nano-grid at a residence or small business location.

This is accomplished in our iteration by deliberately staying away from proprietary control systems and using our device as a substitution for an actual hands on user/operator. Our device looks at all of the information from a third-party perspective and then checks internal directives and algorithms to decide which buttons to push, relays to open, or signals to send to outside sources, controllers, interfaces, and transducers, etc. in order to operate a nanogrid in the desired fashion. The Mark 1 operator will treat all devices on the nanogrid generically and will remain agnostic to brands and/or control platforms, thus enabling the nanogrid manager to use existing equipment and/or add and delete equipment with little thought towards equipment control interoperability.

The Mark 1 also has integral to its structure, the ability to communicate to the “grid world” via the IoE (Internet of Energy) and the IoT (Internet of Things) in order to receive and provide information relating to energy market arbitrage, ancillary service needs, and available renewable power on the grid such as night time wind power from the CREZ's (competitive renewable energy zones) in Texas, expected weather patterns, etc. thus allowing the user to participate in the future energy paradigm of local responsibility and to engage as desired in aggregator directed arbitrage for grid contributions.

This concept when fulfilled in many of numerous ways consists of three parts.
1. The “brain” can be manifested in any of several designs and methods, all of which will accomplish at minimum:
   a. Receive inputs from sensors and transducers placed strategically throughout the nano-grid to gather and correlate relevant data pertaining to nano-grid operation.
   b. “Digest” data following built-in guidelines to properly arrange and execute control operations for nano-grid operations.
   c. Enable, engage, disable, and/or disengage various devices and situations in the nano-grid from a generally external viewpoint using transducers and/or codings placed strategically throughout the nano-grid in accomplish conformity to programmed nano-grid directives.
   d. Communicate via the “cloud” or other methods with interested parties including but not limited to aggregation companies, weather stations, other nano-grids, and nano-grid operators in order to accomplish the best use of available energy resources both individually and as an “energy ring” of nano-grids.
2. The “nervous system” can be manifested in any of several designs and methods, all of which will accomplish at minimum:
   a. Carry data to and from sensor and input transducer nodes, thus connecting the “brain” to the nano-grid regarding data.
   b. Connect transducers and other operating control devices and constructs to the “brain” allowing direct control of the nano-grid and/or its components. These sensors and transducers will be non-intrusive to the equipment and systems being monitored unless specifically and deliberately engineered otherwise.
   c. Connect transducers, other operating control devices, and systems to the “brain” via control signals either analog, digital, or other allowing indirect control of the nano-grid as deliberately designed and engineered for specific sites and/or and situations.
3. The “muscle group” can be manifested in any of several designs and methods, all of which will accomplish at minimum:
   a. Enable, engage, disable, and/or disengage various devices and situations in the nano-grid via remote or direct relays, signals, and/or other methods to accomplish control of the nano-grid to programmed specifications.
   b. Enable, engage, disable, and/or disengage various devices and situations in the nano-grid via remote or direct relays, signals, and/or other methods to accomplish input of relevant data and/or information for best operation of the nano-grid.

The system consists of:
Universal Nanogrid Operator Core (Universal Operator)
Nanogrid interface/sensor equipment
Nanogrid response/action equipment

### The Nanogrid Operator Core Consists of at Minimum

1. A data/information receipt system which may include without being limited to:
a. Inputs to the operator core reflecting nanogrid status as reported from nanogrid sensor/interface kits.
   May include without being limited to data from: voltage sensors (ac and dc), current sensors (ac and dc), temperature sensors, irradiance sensors, wind data sensors, battery state of charge sensors, and/or any other type or group of information gathering equipment useful to the nanogrid operator in fulfilling its purpose of regulating nanogrid operations for maximum usability and value.
b. Inputs to core reflecting real time events.
   May include without being limited to: real-time clock data for further analysis in core, scheduled event timing data for further analysis in core, and/or any other type or group of timing information useful to the nanogrid operator in fulfilling its purpose of regulating nanogrid operations for maximum usability and value.
c. Inputs to core reflecting data received from outside sources which may include without being limited to:
   OFF-SITE: May include while not being limited to: preprocessed data delivered to the nanogrid operator from various off-site sources such as NREL workgroups, third party aggregation firms, and/or specific utility data interfaces, and/or any other type or group of information sharing protocols useful to the nanogrid operator in fulfilling its purpose of regulating nanogrid operations for maximum usability and value.
   ON-SITE: May include while not being limited to: site data from weather station, processed forecasting data, distributed sensor arrays, and/or any other type or group of data from information gathering equipment useful to the nanogrid operator in fulfilling its purpose of regulating nanogrid operations for maximum usability and value.

2. A data processing/correlation system which may include without being limited to:
a. A device or group of devices which analyzes received data and/or system status information and correlates it with specified instruction sets and/or any other type or group of information useful to the nanogrid operator in fulfilling its purpose of regulating nanogrid operations for maximum usability and value.

3. A response/action system which may include without being limited to:
a. Core-controlled relays connected to nanogrid nodes.
b. Core-controlled relays connected to nanogrid response/action kits which are placed strategically throughout the nanogrid.
c. Command data transfer methods and/or equipment for communicating with nanogrid response/action kits which are placed strategically throughout the nanogrid.
d. Data transfer methods for communicating with “third party” collaborators such as NIRE and NREL and/or others in the renewable Industry which have desirable services to offer the nanogrid operators

### The Nanogrid Interface/Sensor Equipment may Include Without Being Limited to

1. Discreet or combined current transformers.
2. Current sense modules. (DC and/or AC)
3. Power flow and direction modules.
4. Voltage sense connections.
5. Voltage sense modules.
6. UL 1741 threshold sense modules.
7. Diversion load sense and step modules.
8. Insolation sense modules.
9. Preprocessing modules which incorporate needed inputs and functions to steer the operator core with coarse status reports grouped from multiple nanogrid nodes.

### The Nanogrid Response/Action Equipment may Include Without Being Limited to

1. Operator controlled relays/contactors for switching of nanogrid power routes to activate/engage predictable nanogrid equipment modes.
2. Strategically placed interface kits throughout the nanogrid which will implement desired nanogrid actions by using operator accessible input states at nanogrid equipment to activate/engage predictable nanogrid equipment modes. Activation of these interface kits by the operator core can be accomplished by many methods including direct connection or networking (hardwired and/or wireless).

Some example nanogrid operator response/action kit descriptions follow:
a. Relay array routing kits.
b. Discreet relays of various poles and power ratings.
c. Discreet contactors of various power ratings.
d. Display kits to inform human operator of system status and events.
e. Translation kits for communicating with off-site third parties.

Some example nanogrid operator controlled response/action kit tasks follow:
a. Preheating/cooling of temperature controlled spaces in preparation for scheduled nanogrid events such as load shifting as a DER.
b. Battery/energy storage maintenance.
c. Electric Vehicle interfacing for bidirectional charging/DER use.
d. Engaging solar PV array sections as needed to control generation output as needed. When in off-grid mode some systems will need to be generation regulated to accomplish nanogrid storage “smart charging”.
e. Engaging diversion loads as needed to most effectively utilize nanogrid energy when in off-grid mode. Having the PV array active and generating into a diversion load will allow for instant disconnect of the diversion load thus having that diverted power instantly available for use in starting air conditioning units or other heavy start loads. The diversion loads can also be used to fine tune smart charging when in off-grid mode.
f. Engaging alternative fuel generator in nanogrid as needed.
g. Regulating all nanogrid energy sources to best accommodate nanogrid operations for maximum usability and value.
h. Regulating all nanogrid loads to best accommodate nanogrid operations for maximum usability and value. During off-grid or Time of Use modes certain loads may be disallowed or conditionally allowed on the nano-grid such as pool pumps, large air conditioning units, electric ranges, etc.
i. Setting up nanogrid state for providing solar generation to utility grid while residence operates on stored power. This can happen as desired and will normally be synchronized with the peak usage times reported by the utility or aggregation company. This energy supplied to the utility during peak usage times may receive greater compensation than average and may coincide with Time of Use rates.
j. Setting up nanogrid state for providing stored energy to the utility grid as desired per Time of Use or aggregator request.
k. Charging of nanogrid storage systems during specified times such as off-peak hours per aggregator and/or for Time of Use cost effective rates.

### EXAMPLES OF THE UNIVERSAL OPERATOR OVERSEEING A FEW SCENARIOS WITH NO CONCERN AS TO EQUIPMENT BRANDINGS

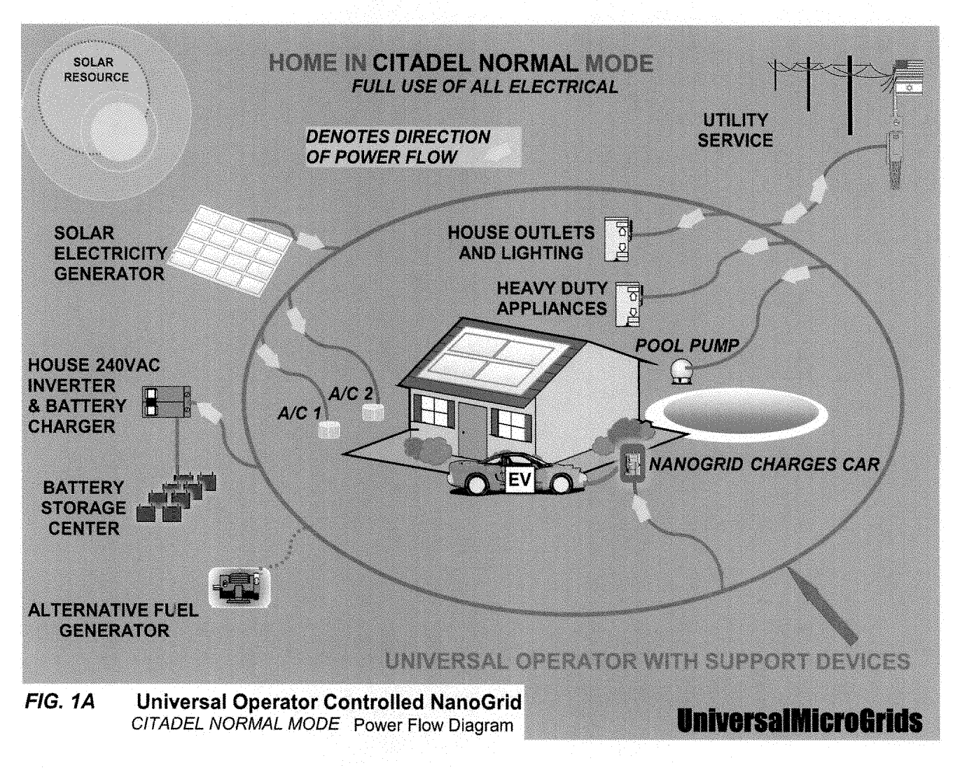

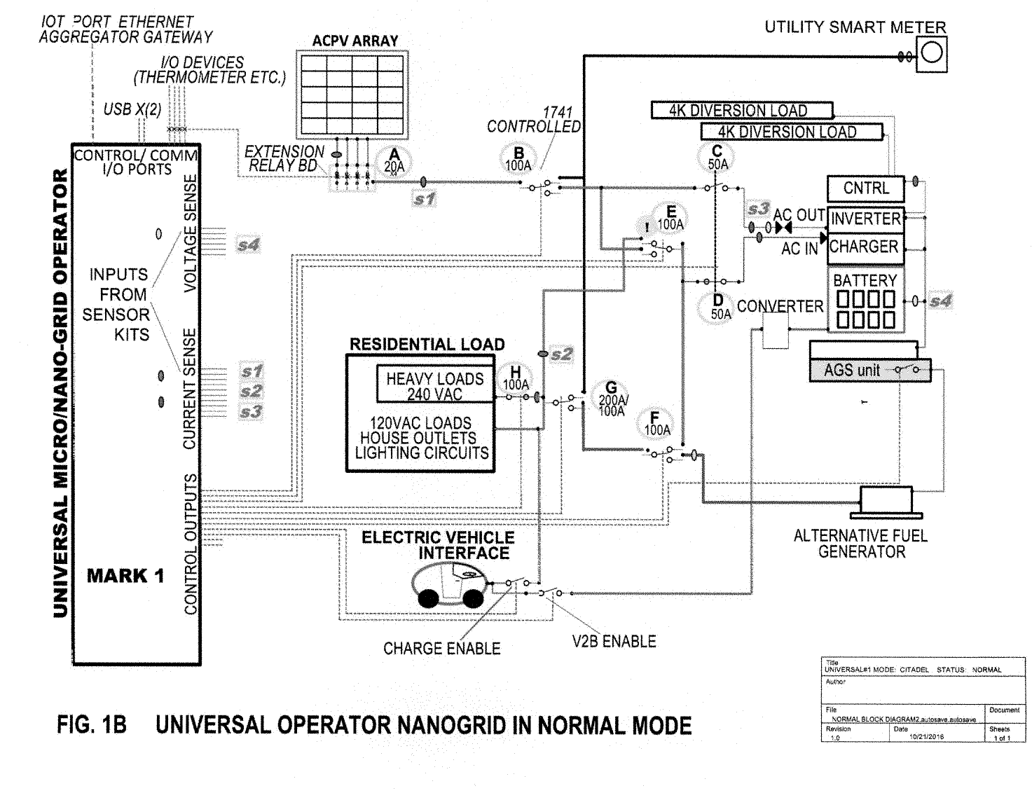

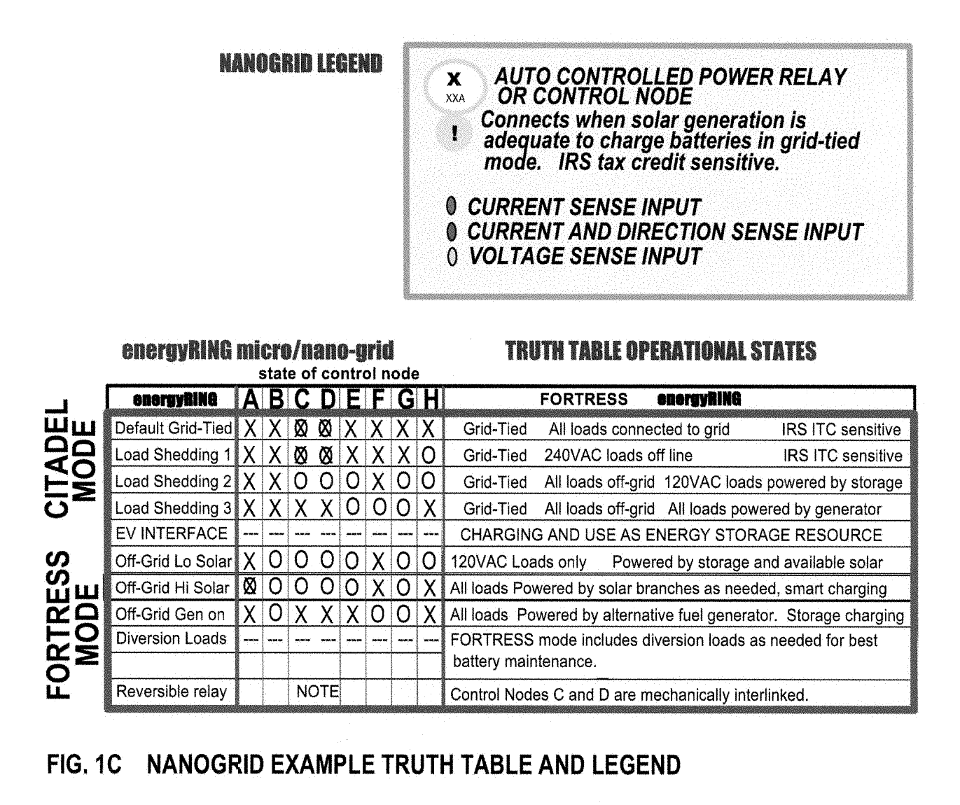

FIG. 1A shows the basic one line drawing of a UNIVERSAL NANOGRID OPERATOR residential nanogrid in NORMAL MODE using any brands of various equipment pieces to complete the nanogrid. Yellow direction arrows denote Universal Operator controlled power flows allowed in this mode.

FIG. 1B shows an example block diagram of this residential nanogrid in NORMAL MODE.

FIG. 1C provides a legend and a truth table to lend clarity to the block diagram.

In FIG. 1A and FIG. 1B our example nanogrid in NORMAL MODE rests in the default state which connects all electrical appliances and storage charging systems to the now present utility grid. The PV array will produce at maximum and will automatically back feed onto the utility grid if production exceeds nanogrid power requirements. The only changeable part of this mode is the UL1741 requirement that PV generation disconnect for at least five minutes if the utility grid voltage or frequency goes out of set parameters. This UL1741 requirement may be satisfied by the internal electronics of the inverters or by the Universal NanoGrid operator, depending on the nanogrid configuration. As drawn, the microinverters of whatever brand in the PV array will automatically disconnect as required. All power in the nanogrid is directed through the Universal Nanogrid Operator default routing system of relays, contactors, and equipment input states that insure nanogrid equipment is performing as intended for the NORMAL MODE.

In NORMAL MODE, the Universal Operator is “hands off” and the default positions of routing relays and contactors remain constant. The residence, from the homeowner's perspective, in NORMAL MODE receives power as needed just as if the residence was connected to the utility grid with no nanogrid installation.

The residential nanogrid example contains a backup alternative fuel generator which can be activated by the Universal NanoGrid Operator as needed in any mode except for NORMAL MODE.

Also, the Universal Operator may have the ability to record all nanogrid states, power flows, and communications in real time for sharing, charting, analysis, etc.

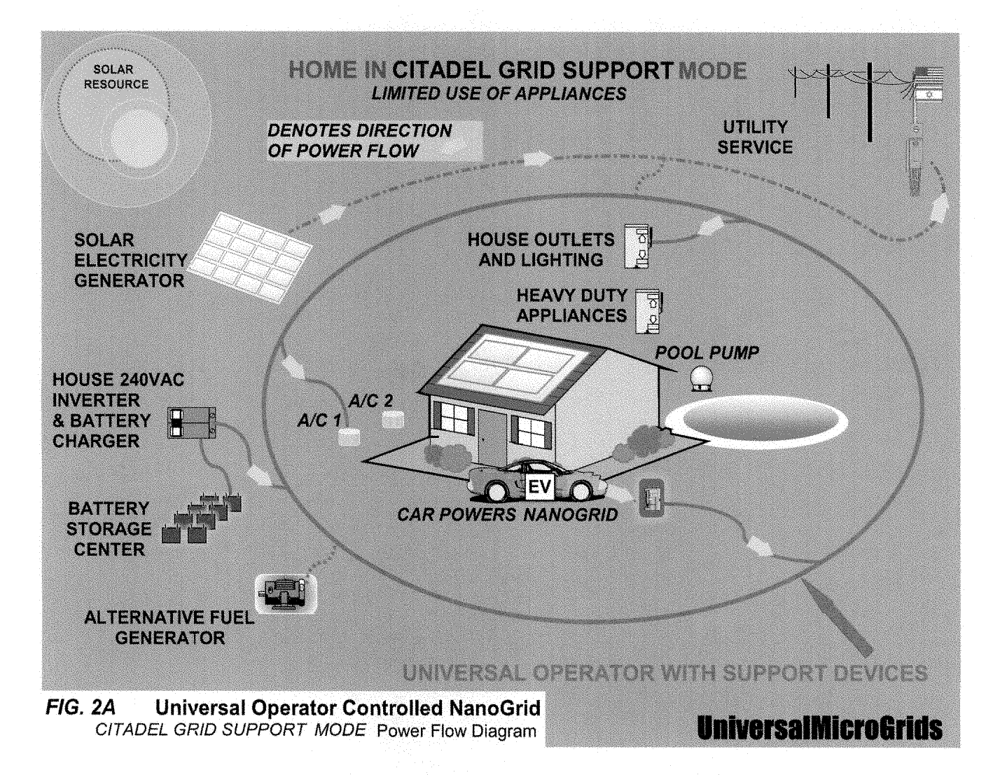

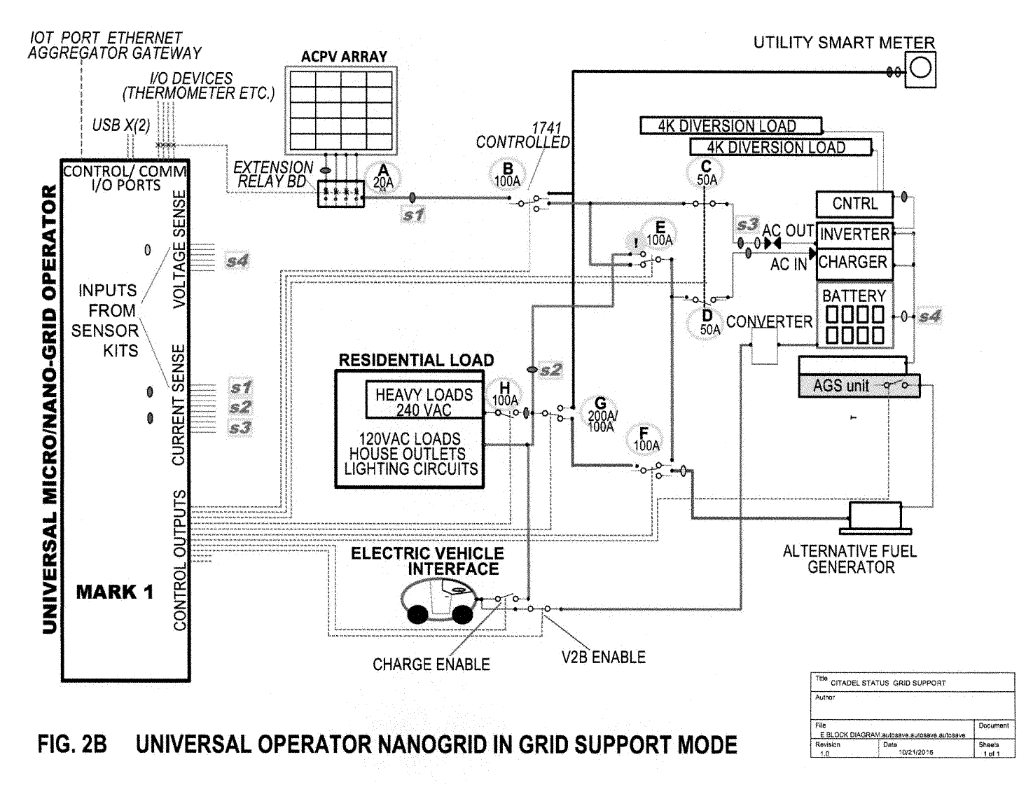

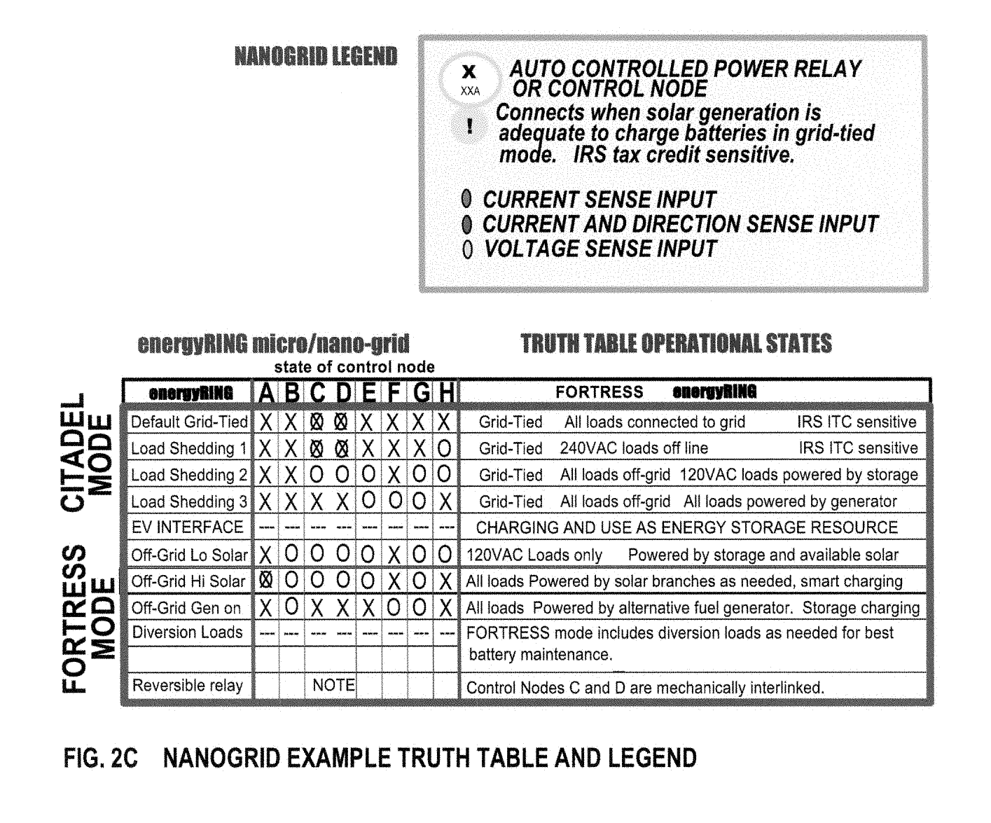

FIG. 2A shows a basic one line drawing of a residential nanogrid in GRID SUPPORT MODE.

FIG. 2B shows an example block diagram of this residential nanogrid in GRID SUPPORT MODE.

FIG. 2C provides a legend and a truth table to lend clarity to the block diagram.

In FIG. 2A and FIG. 2B our example nanogrid is in GRID SUPPORT MODE and is operating independently of the utility grid while diverting all PV production directly to the utility grid. The Universal Operator normally is called on to configure this mode for Time of Use rate benefits or just to be helpful to the utility grid in times of peak usage. The action to go into GRID SUPPORT MODE may be made autonomously by the homeowner, scheduled ahead of time to meet expected utility grid situations, or suggested via communication with a third party aggregator as real time grid conditions change.

Note that the Universal NanoGrid Operator has opened and closed different power paths to efficiently configure this GRID SUPPORT MODE. The PV array is connected directly to the utility grid to provide solar electricity to the utility grid while the residential NanoGrid is connected to the battery powered house inverter/generator for power to all house circuits. The Universal Operator may disconnect certain heavy load circuits such as main a/c unit, electric ranges, pool pumps, etc. as determined by real-time nanogrid conditions and preplanned activity paths. The Universal Operator also determines if and when the Electric Vehicle battery system should be used to supplement the on-site house battery storage system. In this diagram the EV battery system is shown in “charge support” mode. The Universal Operator configures these conditions by simple coordinated relay and contactor actions. The internal working programs of the nanogrid equipment have no control connection to the Universal Operator, but simply respond to the circuits that are connected and disconnected to their various inputs according to their internal programming. Thus the homeowner can change out a piece of equipment and not have to reprogram a complicated control system. The new piece will fit right into the nanogrid and the Universal Operator may be reset to match the instruction manual for the new equipment without requiring proprietary software or coding.

UNIVERSAL NANOGRID OPERATOR programming is done using the instruction manuals of the chosen nanogrid equipment as guides to accurately predict equipment states as preplanned nanogrid configurations are presented via power routing and simple switching changes.

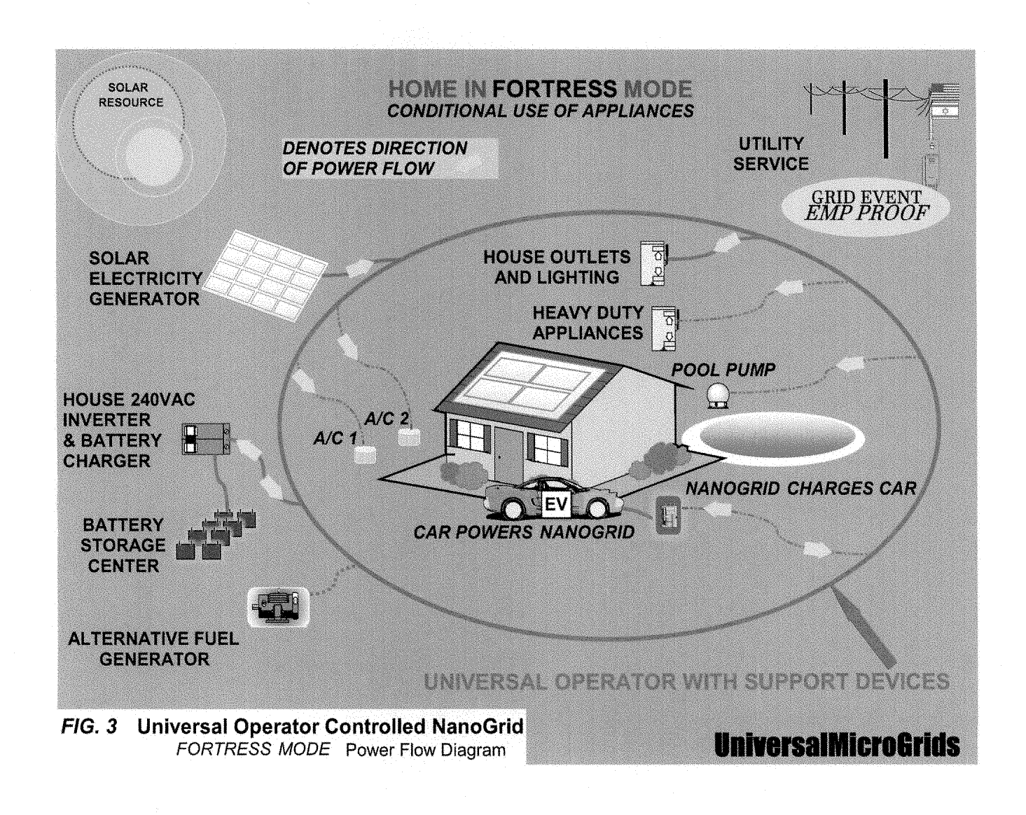

In FIG. 3 our example nanogrid in FORTRESS MODE is operating independently of the utility grid and has severed all utility grid connections. The Universal Operator may set this nanogrid mode because of homeowner choice, utility grid failure, or from expected danger of an EMP grid event.

In the FORTRESS MODE the Universal Operator will monitor available solar power and storage state of charge and determine which appliance sets to enable in order to meet the desired nanogrid criteria.

If the Universal Operator engages the backup generator it will also disconnect the solar array and connect the battery charger until the backup generator charging cycle is complete. While the backup generator is charging the nanogrid the Universal Operator will also allow heavy load appliances and EV charging depending on the amount of power available from the backup generator.

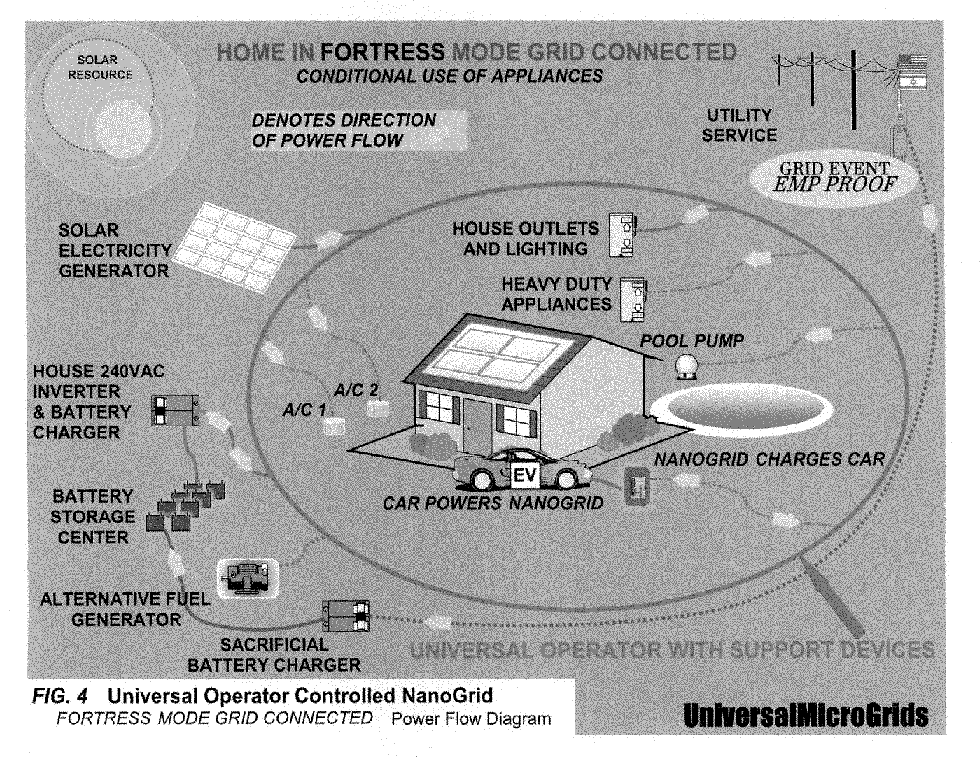

In FIG. 4 our example nanogrid in FORTRESS MODE WITH GRID is operating independently of the utility grid with the exception that the Universal Operator has connected an additional “sacrificial” battery charger which keeps the house batteries at full charge as long as the grid is functional. This mode is for those who do not want to have their nanogrid connected to the utility grid when an EMP grid event occurs but still want access to grid power. By inserting a battery charging system between the utility grid and the house inverter/charger the nanogrid is isolated from all but the most audacious EMP event which would have caused equipment damage even with the nanogrid disconnected from the utility grid. The homeowner must be willing to “sacrifice” the connected charging system as it protects the rest of the nanogrid by absorbing the EMP surge to its own demise.

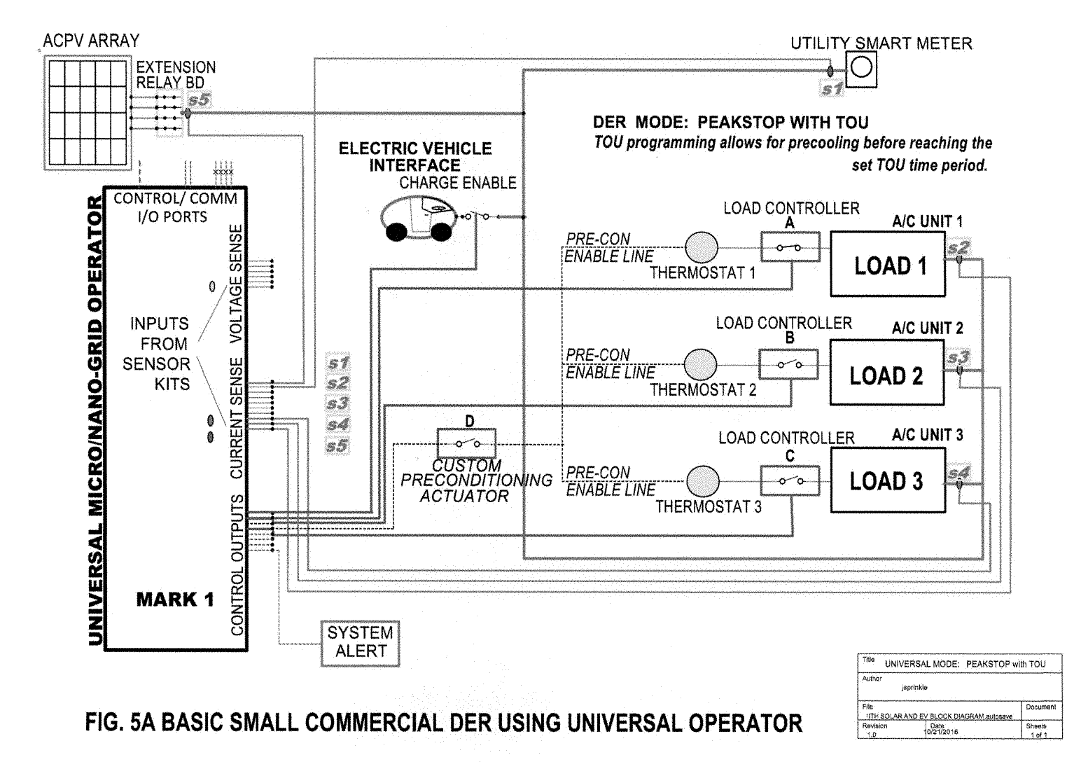

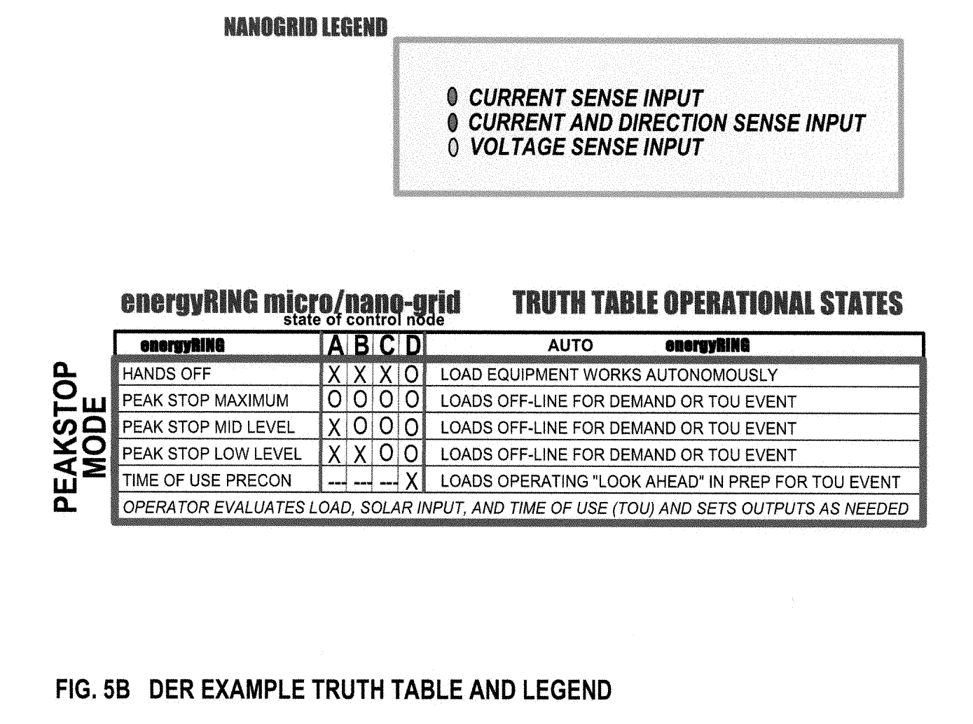

In FIG. 5A our Universal Operator is overseeing a partial nanogrid which has solar PV generation without storage. The Universal Operator will use third party information, real-time scheduling, and/or autonomous determination of when to shave loads as it watches all electrical aspects of this small commercial DER project including the “health” of the compressor loads. FIG. 5B offers a legend and truth table for clarity.

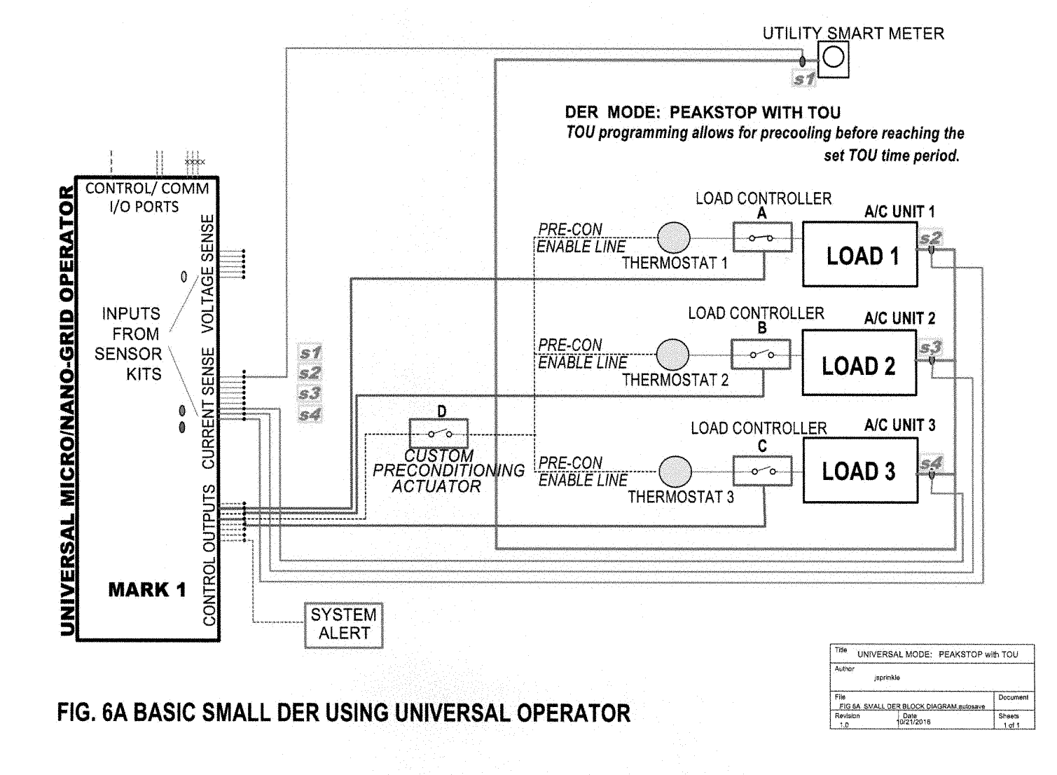

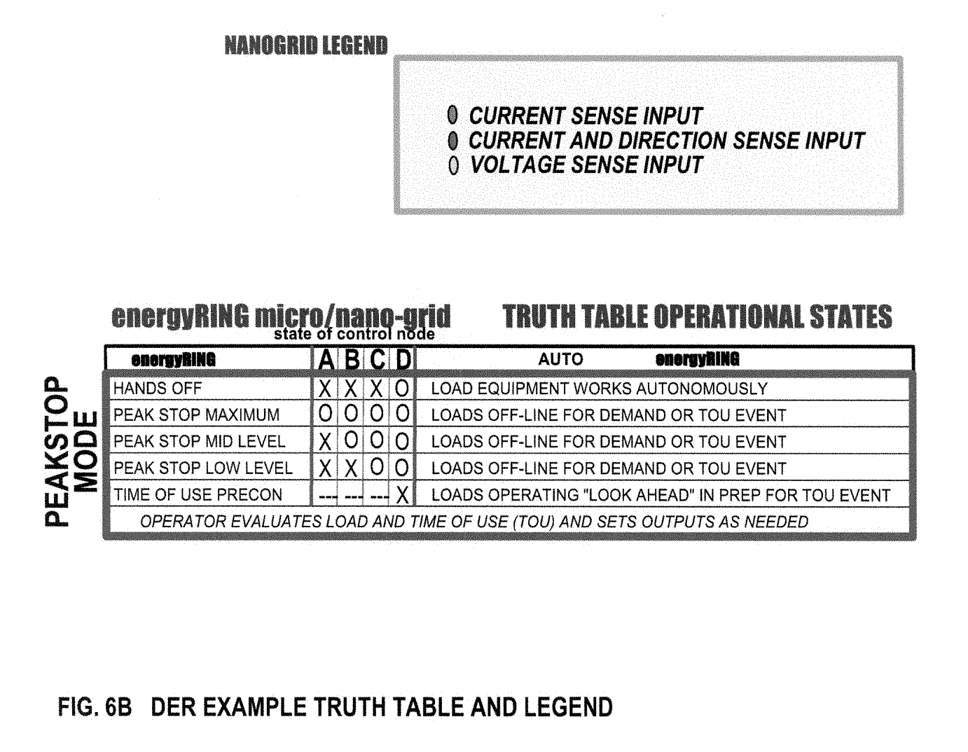

In FIG. 6A our Universal Operator is overseeing a simple small commercial DER project with the purpose of using TOU rate differences and demand charge caps to lower the electricity bill while helping the utility control demand peaks. FIG. 6B offers a legend and truth table for clarity.

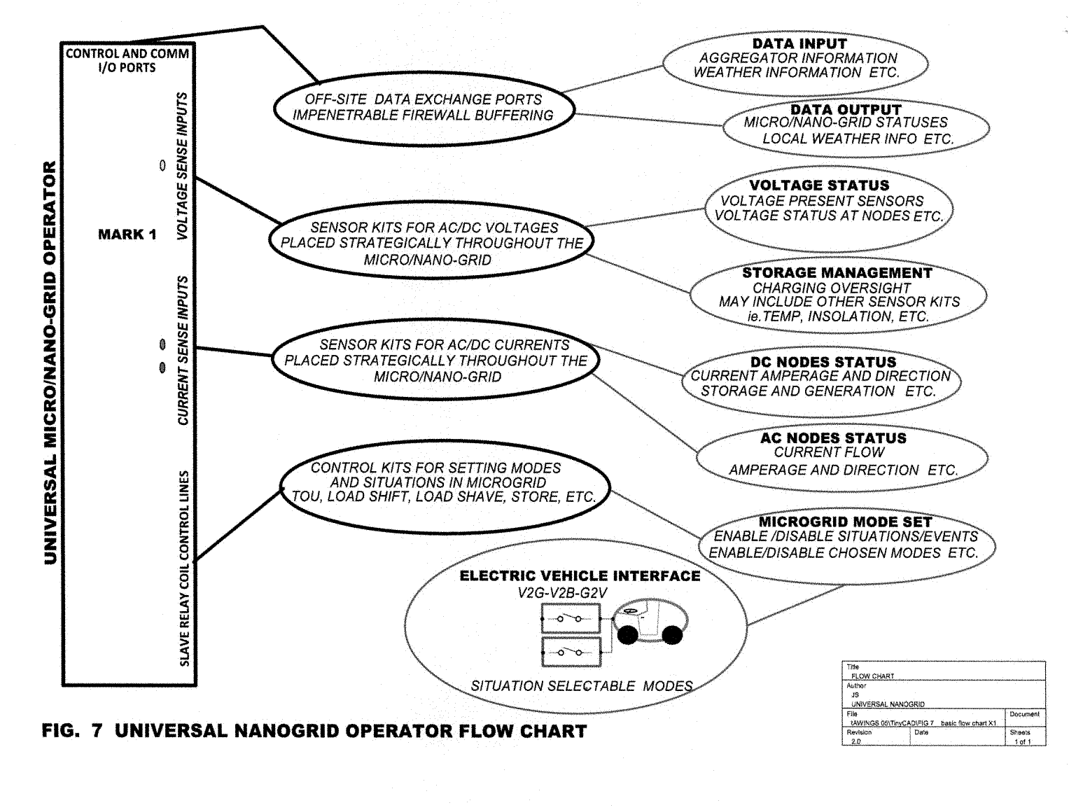

FIG. 7 Offers an example “flow chart” of a basic nanogrid being operated by the Universal NanoGrid Operator.

The original test device (MARK 1) which has successfully operated all equipment groupings as desired is the complete operator core on one custom designed circuit board with inputs and outputs as needed to properly operate a residential nanogrid. This universal operator core is coupled to discreet sensor kits such as current transformers and action transducers such as contactors and relays to complete the nanogrid control system. A real-time clock is built into this circuit board as well as network communication capabilities for working with third party aggregators and other interested partners.

We are claiming a unique device:

1. (Universal Nanogrid Operator System) designed for universal application in small to medium sized nanogrids using any brand and/or grouping of equipment that has predictable operating protocols which the Universal NanoGrid Operator can engage with simple high level actions rather than proprietary internal system communication. The operator core may be a group of components on one circuit board or may be multiple groups of components working together as one to make up the operator core. This operator core will accomplish the task of easily operating today's nanogrids using sensor kits and transducer kits while being universally flexible in meeting the needs of tomorrow's nanogrids.
Because our device is designed for this operational context it allows almost unlimited flexibility in equipment choices, changes, and additions at the nanogrid level without complicated interfaces and/or bottlenecks between equipment types and brands.
We are also claiming a unique device

2. (Universal Nanogrid Operator Core) which is used to monitor and operate the sensors and transducers used in the universal nanogrid operator system.
